(19) United States
(12) Patent Application Publication
(10) Pub. No.: US 2021/0349260 A1
(43) Pub. Date: Nov. 11, 2021

(54) OPTICAL MODULE

(71) Applicant: Nippon Telegraph and Telephone Corporation, Tokyo (JP)

(72) Inventors: Toshiki Kishi, Tokyo (JP); Hitoshi Wakita, Tokyo (JP); Kota Shikama, Tokyo (JP); Shigeru Kanazawa, Tokyo (JP); Yuko Kawajiri, Tokyo (JP); Atsushi Aratake, Tokyo (JP)

(21) Appl. No.: 17/277,632

(22) PCT Filed: Sep. 27, 2019
(86) PCT No.: PCT/JP2019/038142

§ 371 Date: Mar. 18, 2021

(30) Foreign Application Priority Data
Oct. 12, 2018 (JP) 2018-193384

(51) Int. Cl. G02B 6/12; G02B 6/42; H01L 23/00; H01L 27/144

(52) U.S. Cl. CPC G02B 6/12; H01L 27/144; H01L 24/14; G02B 6/42

(57) ABSTRACT

The optical module includes an extension circuit board and a front end flip-chip mounted on the extension circuit board. The front end includes a semiconductor amplifier chip that executes signal processing, and an optical semiconductor chip that includes at least one of a light emitting element and a light receiving element and is flip-chip mounted on the semiconductor amplifier chip. The extension circuit board has a recessed portion that can accommodate at least a part of the optical semiconductor chip. The semiconductor amplifier chip is flip-chip mounted on the extension circuit board in the state where the surface mounting the optical semiconductor chip faces the surface of the extension circuit board, and at least a part of the optical semiconductor chip is accommodated in the recessed portion.

### CROSS-REFERENCE TO RELATED APPLICATIONS

This application is a national phase entry of PCT Application No. PCT/JP2019/038142, filed on Sep. 27, 2019, which claims priority to Japanese Application No. 2018-193384, filed on Oct. 12, 2018, which applications are hereby incorporated herein by reference.

### TECHNICAL FIELD

The present invention relates to an optical module, and in particular, to a compact optical module using flip-chip mounting.

### BACKGROUND

In recent years, due to the significant development of social networking services (SNSs), the amount of communication traffic throughout the world has increased. In the future, a further increase in the amount of communication traffic is expected due to the development of the Internet of things (IoT) and cloud computing technology, and there is a demand for a larger communication capacity in and out of a data center to support a vast amount of traffic. However, as the capacity increases, the scale of the data center increases, resulting in a decrease in communication capacity per unit area.

With increasing capacity, according to the standard for Ethernet (registered trademark), which is a primary standard element of the network, the standardization of 10 GbE, 40 GbE has been completed, and for a larger capacity, the standardization of 100 GbE has been nearly completed. In the process of the standardization of 100 GbE, the miniaturization of the interface of the optical transceiver has been studied, and a very compact interface CFP4 (Centum gigabit Form factor Pluggable) has been reported (see Non Patent Literature 1 and Non Patent Literature 2).

In the compact optical transmission/reception module disclosed in Non Patent Literature 1 and Non Patent Literature 2, a driver for driving a laser diode (LD) is joined to the LD via a wire, and a transimpedance amplifier (TIA) for driving a photo diode (PD) is joined to the PD via a wire. In a module on the transmission side, light output from the LD is focused through the lens and transmitted to a receiver module via a fiber. In the receiver module, light output from the fiber is received at the PD and converted into an electrical signal at the TIA.

As described above, in the optical transmission/reception module disclosed in Non Patent Literature 1 and Non Patent Literature 2, since the driver and the LD, and the TIA and the PD are bonded to each other via the wire, disadvantageously, the band is degraded in relation to the wiring length and the area of the modules is increased by the wire bonding structures.

### CITATION LIST

### Non Patent Literature

Non Patent Literature 1: A. Moto, T. Ikagawa, S. Sato, Y. Yamasaki, Y. Onishi, and K. Tanaka, “A low power quad 25.78-Gbit/s 2.5 V laser diode driver using shunt-driving in 0.18 μm SiGe-BiCMOS”, Compound Semiconductor Integrated Circuit Symposium, 2013; and

Non Patent Literature 2: Tomoya Saeki et al., “Compact Optical Transmitter Module with Integrated Optical Multiplexer for 100 Gbit/s”, SEI Technical Review No.188, January, 2016.

### SUMMARY

### Technical Problem

Embodiments of the present invention are devised to solve the above problems and intends to provide a more compact optical module capable of suppressing degrading of the band than the related-art optical modules.

### Means for Solving the Problem

An optical module of embodiments of the present invention includes: a circuit board; and a front end flip-chip mounted on the circuit board, wherein the front end includes: a semiconductor amplifier chip configured to execute signal processing; and an optical semiconductor chip including at least one of a light emitting element and a light receiving element, the optical semiconductor chip being flip-chip mounted on the semiconductor amplifier chip, the circuit board has a recessed portion configured to accommodate at least a part of the optical semiconductor chip, and the semiconductor amplifier chip is flip-chip mounted on the circuit board in a state where a surface mounting the optical semiconductor chip faces a surface of the circuit board and at least a part of the optical semiconductor chip is accommodated in the recessed portion of the circuit board.

In one configuration example of the optical module of embodiments of the present invention, the semiconductor amplifier chip is rectangular in a top view, has a width where at least one side is larger than a width of the optical semiconductor chip and a width of the recessed portion of the circuit board, and includes a first electrode for connection to the optical semiconductor chip, the first electrode being formed on the surface mounting the optical semiconductor chip, and a second electrode for connection to the circuit board, the second electrode being formed in a region outer than the first electrode mounting the optical semiconductor chip, the first electrode is connected to a third electrode formed on the surface of the optical semiconductor chip via a bump, and the second electrode is connected to a fourth electrode formed around the recessed portion of the circuit board via a bump.

Further, in one configuration example of the optical module of embodiments of the present invention, the circuit board further includes a solder ball electrically connected to the fourth electrode on a back surface opposite to the surface mounting the semiconductor amplifier chip.

Further, in one configuration example of the optical module of embodiments of the present invention, the circuit board further includes a fifth electrode for wire bonding, the fifth electrode being electrically connected to the fourth electrode on the surface mounting the semiconductor amplifier chip.

In a configuration example of the optical module of embodiments of the present invention, the semiconductor amplifier chip further includes a dummy electrode at a position on a surface facing the optical semiconductor chip, and a bump on the dummy electrode is in contact with the surface of the optical semiconductor chip or the dummy electrode is connected to a dummy electrode formed on the surface of the optical semiconductor chip via a bump.

Further, in one configuration example of the optical module of embodiments of the present invention, the recessed portion of the circuit board is formed to reach an end face of the circuit board, and a fiber array is adhesively fixed to an end face of the optical semiconductor chip, the end face of the optical semiconductor chip being exposed from the circuit board, such that the optical semiconductor chip is optically coupled to fibers in the fiber array.

Further, in one configuration example of the optical module of embodiments of the present invention, the end face of the optical semiconductor chip is flush with the end face of the circuit board, and the fiber array is adhesively fixed to the end face of the optical semiconductor chip and the end face of the circuit board.

### Effects of Embodiments of the Invention

According to embodiments of the present invention, the optical semiconductor chip is flip-chip mounted on the semiconductor amplifier chip, and further, the semiconductor amplifier chip is flip-chip mounted on the circuit board in the state where the surface of the semiconductor amplifier chip, which mounts the optical semiconductor chip thereon, faces the surface of the circuit board, and at least a part of the optical semiconductor chip is accommodated in the recessed portion of the circuit board. As a result, according to embodiments of the present invention, the wiring length between the optical semiconductor chip and the semiconductor amplifier chip becomes smaller as compared to the related-art wire bonding, thereby suppressing the band degradation of the optical module. In addition, according to embodiments of the present invention, the wire bonding structure is not necessary, which enables manufacturing of a compact optical module.

### BRIEF DESCRIPTION OF THE DRAWINGS

FIG. 1 is a set of a front view and an enlarged view of an optical transmission/reception module according to a first embodiment of the present invention.

FIG. 2 is a set of a side view and a top view of the optical transmission/reception module according to the first embodiment of the present invention.

FIG. 3 is a top view of a semiconductor amplifier chip of the optical transmission/reception module according to the first embodiment of the present invention.

FIG. 4 is a set of a side view and a top view illustrating another example of the optical transmission/reception module according to the first embodiment of the present invention.

FIG. 5 is a set of a side view and a top view illustrating another example of the optical transmission/reception module according to the first embodiment of the present invention.

FIG. 6 is a set of a side view and a top view illustrating another example of the optical transmission/reception module according to the first embodiment of the present invention.

FIG. 7 is a front view of an optical transmission module according to a second embodiment of the present invention.

FIG. 8 is a set of a side view and a top view of the optical transmission module according to the second embodiment of the present invention.

FIG. 9 is a set of a front view and an enlarged view illustrating another example of the optical transmission module according to the second embodiment of the present invention.

FIG. 10 is a set of a side view and a top view illustrating the other example of the optical transmission module according to the second embodiment of the present invention.

FIG. 11 is a front view of an optical reception module according to a third embodiment of the present invention.

FIG. 12 is a set of a side view and a top view of the optical reception module according to the third embodiment of the present invention.

FIG. 13 is a set of a front view and an enlarged view illustrating another example of the optical reception module according to the third embodiment of the present invention.

FIG. 14 is a set of a side view and a top view illustrating the other example of the optical reception module according to the third embodiment of the present invention.

FIG. 15 is a front view of an optical transmission/reception module according to a fourth embodiment of the present invention.

FIG. 16 is a view explaining dimensions of the modules according to the first to fourth embodiments of the present invention.

### DETAILED DESCRIPTION OF ILLUSTRATIVE EMBODIMENTS

### Principles of Embodiments of the Invention

A means for solving the problems described above include embodiments of the present invention, in which a driver and LD are flip-chip bonded, TIA and PD are flip-chip bonded, and a flip-chip bonded transmission and receiving front end is flip-chip bonded to the circuit board having a cavity structure. In this manner, according to embodiments of the present invention, the wiring length between the driver and the LD and the wiring length between the PD and the TIA become smaller as compared to the related-art wire bonding, thereby suppressing the band degradation of the optical modules (an optical transmission/reception module, an optical transmission module, and an optical reception module). In addition, the wire bonding structure is not necessary, which enables manufacturing of a compact optical module.

### First Embodiment

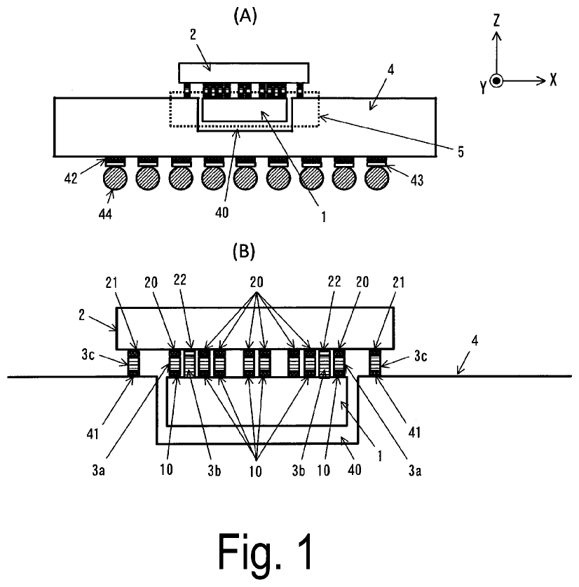

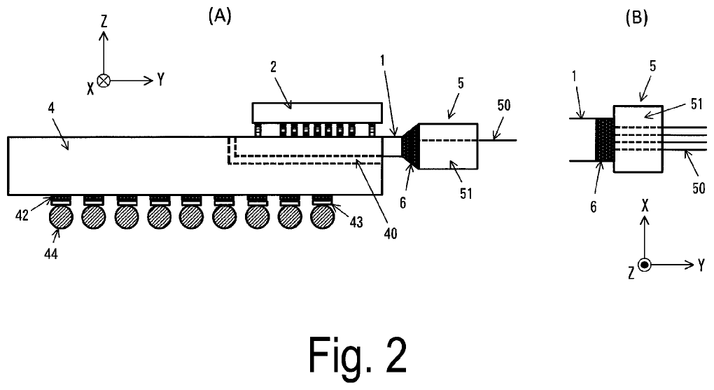

Hereinafter, a first embodiment of the present invention will be described with reference to the drawings. FIG. 1(A) is a front view of an optical transmission/reception module according to the first embodiment of the present invention. FIG. 1(B) is an enlarged view of a joined portion between a semiconductor amplifier chip and an optical semiconductor chip of the optical transmission/reception module in FIG. 1(A). FIG. 2(A) is a side view of the optical transmission/reception module in FIG. 1(A). FIG. 2(B) is a top view of a coupling portion between the optical transmission/reception module in FIG. 2(A) and a fiber array. For ease of viewing the structure of the optical transmission/reception module, a fiber array 5 described below is indicated by a dotted line in FIG. 1(A), and the description of the fiber array 5 is omitted in FIG. 1(B).

In the case of the optical transmission/reception module in the present embodiment, an LD (light emitting element, not illustrated) for transmission and a PD (light receiving element, not illustrated) for reception are mounted on an optical semiconductor chip 1. A driver (not illustrated) for driving the LD and a TIA (not illustrated) for amplifying a current signal output from the PD and converting the current signal into a voltage signal are mounted on a semiconductor amplifier chip 2 for signal processing. Surface electrodes 10 (the third electrode) connected to a circuit of the optical semiconductor chip 1 are formed on the surface of the optical semiconductor chip 1. Similarly, surface electrodes 20 (the first electrodes) and surface electrodes 21 (the second electrodes) that are connected to a circuit of the semiconductor amplifier chip 2 are formed on the surface of the semiconductor amplifier chip 2.

The optical semiconductor chip 1 is flip-chip mounted on a semiconductor amplifier chip 2. In other words, as illustrated in FIG. 1(B), the surface electrode 10 of the optical semiconductor chip 1 and the corresponding surface electrode 20 of the semiconductor amplifier chip 2 are electrically connected via a bump 3a. This connection enables transmission/reception of signals between the optical semiconductor chip 1 and the semiconductor amplifier chip 2, and power supply to the optical semiconductor chip 1 via the semiconductor amplifier chip 2.

Examples of the material for the surface electrodes 10 of the optical semiconductor chip 1 include Au. The surface electrodes 20, 21 of the semiconductor amplifier chip 2 are made of a material such as Au or Al. The bumps 3a are made of a material such as Au, Al, Cu, or Sn.

When the surface of the optical semiconductor chip 1, which forms the surface electrodes 10 thereon, is inverted (face-down) to flip-chip mount the optical semiconductor chip 1 on the semiconductor amplifier chip 2, it is necessary to prevent the optical semiconductor chip 1 from being inclined and mounted. For this reason, in addition to the surface electrodes 20, 21, dummy electrodes 22 for preventing the optical semiconductor chip 1 from being inclined are formed on the surface of the semiconductor amplifier chip 2. The dummy electrodes 22 are not connected to the internal circuit of the semiconductor amplifier chip 2.

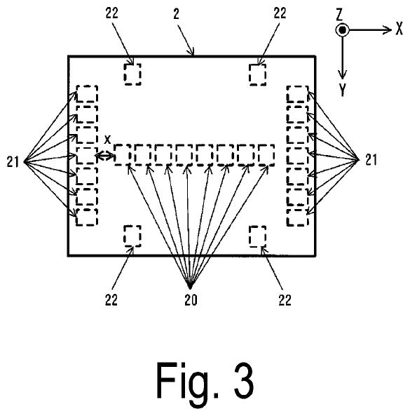

FIG. 3 is a top view of the semiconductor amplifier chip 2 in the state illustrated in FIG. 1(A), FIG. 1(B), and FIG. 2(A) when viewed from above. As described above, in addition to the surface electrodes 20 and the surface electrodes 21 for connection to an extension circuit board 4 described later, the dummy electrodes 22 are formed on the rectangular semiconductor amplifier chip 2 in a top view. A bump 3b is formed on the corresponding dummy electrode 22. Similar to the bumps 3a, the bumps 3b are made of a material such as Au, Al, Cu, or Sn.

When the surface of the optical semiconductor chip 1, which forms the surface electrodes 10 thereon, is inverted (face-down) to flip-chip mount the optical semiconductor chip 1 on the semiconductor amplifier chip 2, the bumps 3b on the dummy electrodes 22 are brought into contact with the surface of the optical semiconductor chip 1. As a result, the inclination of the optical semiconductor chip 1 can be prevented, so that the optical semiconductor chip 1 can be horizontally mounted on the semiconductor amplifier chip 2.

In the example in FIG. 1(B), the bumps 3b formed on the respective dummy electrodes 22 are in contact with the surface of the optical semiconductor chip 1, but dummy electrodes may be formed on the surface of the optical semiconductor chip 1 so as to face the respective bumps 3b, and be connected to the bumps 3b in flip-chip mounting.

In order to prevent the optical semiconductor chip 1 from being inclined, one or more dummy electrodes 22 are required to be disposed on both sides of the surface electrodes 20 for connection to the optical semiconductor chip 1 as illustrated in FIG. 3. In the example in FIG. 3, two dummy electrodes 22 are disposed on both sides of the surface electrodes 20 respectively.

In order to flip-chip mount a transmission/reception front end constituted of the semiconductor amplifier chip 2 and the optical semiconductor chip 1 that are bonded to each other in this manner on the extension circuit board 4, the extension circuit board 4 has a cavity structure having a recessed portion 40 that can accommodate the optical semiconductor chip 1. The extension circuit board 4 is configured of a dielectric substrate made of ceramic, resin, Si, or the like for example.

In order that the optical semiconductor chip 1 accumulated in the recessed portion 40 can hang from the semiconductor amplifier chip 2, the width of the recessed portion 40 (the dimension in the X direction in FIGS. 1(A) and 1(B)) is made larger than the width of the optical semiconductor chip 1 and smaller than the width of the semiconductor amplifier chip 2. The depth of the recessed portion 40 (the dimension in the Z direction in FIGS. 1(A) and 1(B)) is set to a value larger than the thickness of the optical semiconductor chip 1. For coupling between the optical semiconductor chip 1 and the fiber array 5 described later, the recessed portion 40 is formed so as to reach the end face of the extension circuit board 4 as illustrated in FIG. 2(A), and a light emitting/incident end face of the optical semiconductor chip 1 is exposed at the end face of the extension circuit board 4.

The transmission/reception front end constituted of the semiconductor amplifier chip 2 and the optical semiconductor chip 1 is flip-chip mounted on the extension circuit board 4 in the state where the surface of the semiconductor amplifier chip 2 which forms the surface electrodes 20 thereon is inverted (face-down). In other words, as illustrated in FIG. 1(B), the surface electrodes 21 of the semiconductor amplifier chip 2 are electrically connected to respective surface electrodes 41 (the fourth electrodes) of the extension circuit board 4 via respective bumps 3c. This connection enables transmission/reception of signals between the transmission/reception front end and the extension circuit board 4 and power supply to the transmission/reception front end via the extension circuit board 4.

The surface electrodes 41 of the extension circuit board 4 are made of a material such as Au or Al. Similarly to the bumps 3a, 3b, the bumps 3c are made of a material such as Au, Al, Cu, or Sn.

In the case where the extension circuit board 4 does not have a cavity structure, it is necessary to connect the semiconductor amplifier chip 2 to the extension circuit board 4 via wires, or to add via structures that enable the semiconductor amplifier chip 2 to penetrate between the surface electrodes and back electrodes. In contrast, in the present embodiment, such via structure can be eliminated by providing the extension circuit board 4 with the cavity structure. The surface electrodes 20 of the semiconductor amplifier chip 2 are connected to the surface electrodes 10 of the optical semiconductor chip 1 by flip-chip bonding, such that the optical semiconductor chip 1 is accommodated in the recessed portion 40 of the extension circuit board 4. Furthermore, the surface electrodes 21 of the semiconductor amplifier chip 2 are connected to the surface electrodes 41 of the extension circuit board 4 by flip-chip bonding, achieving the smallest wiring length for connection.

Back electrodes 42 for ball grid array (BGA) is provided on the back surface of the extension circuit board 4. The back electrodes 42 are electrically connected to the respective surface electrodes 41 by via structures (not illustrated) in the extension circuit board 4. The back electrodes 42 are made of a material such as Au or Al.

A solder ball 44 can be mounted on the back electrode 42 using a conductive adhesive 43 (for example, cream solder). Providing the optical transmission/reception module with solder balls 44 facilitates mounting of the BGA on the board of the optical transmission/reception module.

Next, as illustrated in FIG. 2(A), the light emitting/incident end face of the optical semiconductor chip 1 exposed from the end face of the extension circuit board 4 is adhesively fixed to the fiber array 5 for optical coupling using an adhesive 6. As a result, optical coupling between an optical waveguide (not illustrated) exposed at the light emitting/incident end face of the optical semiconductor chip 1 and fibers 50 of the fiber array 5 is realized, thereby realizing light output from the LD of the optical semiconductor chip 1 to the fibers 50 and light input from the fibers 50 to the PD of the optical semiconductor chip 1.

As illustrated in the side view in FIG. 2(A) and the top view in FIG. 2(B), the fiber array 5 is configured such that the plurality of fibers 50 are fixed by a fiber block 51. The fiber block 51 is made of a material such as glass or Si. Examples of the fiber 50 include single mode fiber (SMF) and multi mode fiber (MMF).

When the applied amount of the adhesive 6 is small, a flared fillet is formed from the light emitting/incident end face of the optical semiconductor chip 1 to the end face of the fiber array 5, and the fiber array 5 is adhesively fixed to the optical semiconductor chip 1.

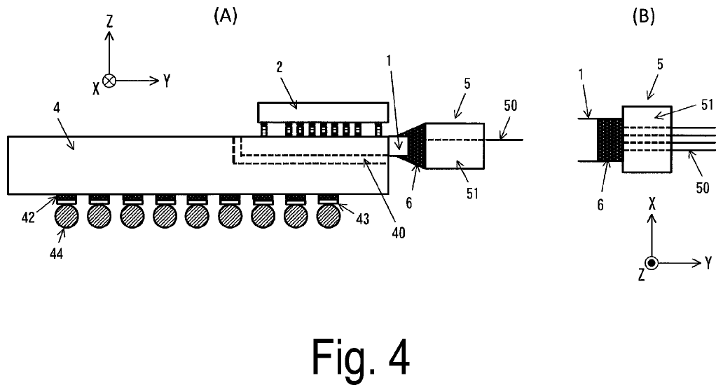

As another example, FIG. 4(A) illustrates a side view of the optical transmission/reception module for the case where the applied amount of the adhesive 6 is large, and FIG. 4(B) illustrates a top view of the coupling portion between the optical transmission/reception module and the fiber array 5 in this case. As illustrated in FIG. 4(A), when the applied amount of the adhesive 6 is large, since a flared fillet is formed from a position near the extension circuit board of the optical semiconductor chip 1 to the end face of the fiber array 5, the amount of the adhesive 6 adhered to the optical semiconductor chip 1 increases as compared to the case of FIG. 2(A), which enables to enhance the adhesive fixation of the fiber array 5.

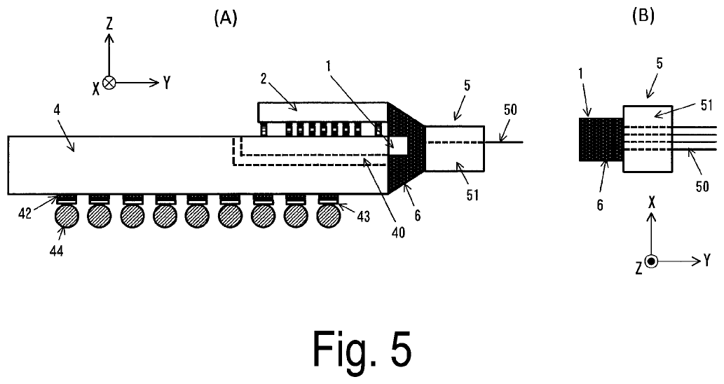

As yet another example, FIG. 5(A) illustrates a side view of the optical transmission/reception module for the case where the applied amount of the adhesive 6 is further increased, and FIG. 5(B) illustrates a top view of the coupling portion between the optical transmission/reception module and the fiber array 5 in this case. As illustrated in FIG. 5(A), by significantly increasing the applied amount of the adhesive 6 to adhere the adhesive 6 to not only the optical semiconductor chip 1, but also the semiconductor amplifier chip 2 and the extension circuit board 4, the adhesive fixation of the fiber array 5 can be enhanced as compared with the case in FIG. 4(A).

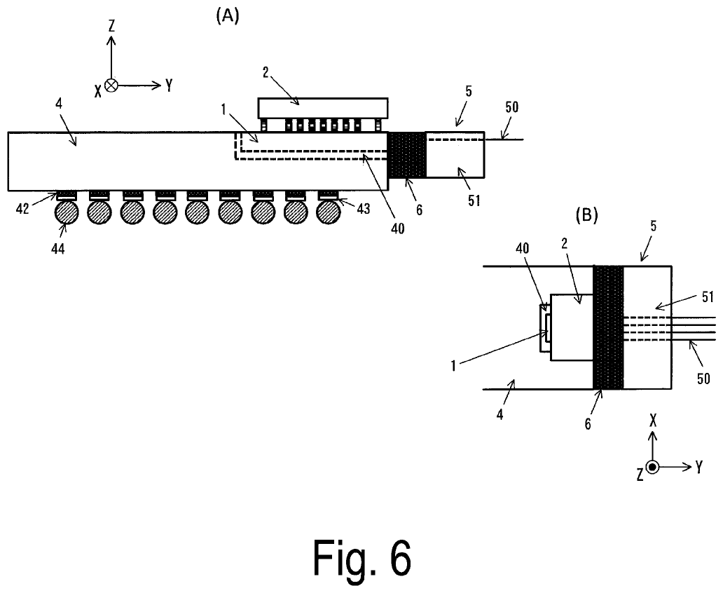

As yet another example, FIG. 6(A) illustrates a side view of the optical transmission/reception module in the case where the light emitting/incident end face of the optical semiconductor chip 1 is flush with the end face of the optical semiconductor amplifier chip 2 and the end face of the extension circuit board 4. Furthermore, FIG. 6(B) illustrates a top view of the coupling portion between the optical transmission/reception module and the fiber array 5 in this case. The light emitting/incident end face of the optical semiconductor chip 1 is flush with the end face of the extension circuit board 4. Thus, when the fiber array 5 is adhered to the light emitting/incident end face of the optical semiconductor chip 1, the end face of the extension circuit board 4 acts as a jig for adhesively fixing the fiber array 5. In this manner, the adhesive fixation of the fiber array 5 can be enhanced.

In addition, in the present embodiment, with respect to the light emitting/incident end face, the end face of the semiconductor amplifier chip 2 does not emerge from the end face of the optical semiconductor chip 1. Therefore, when the semiconductor amplifier chip 2 is adhered to the optical semiconductor chip 1 with an underfill agent or the like, the underfill agent can be prevented from flowing out to the end face of the optical semiconductor chip 1.

### Second Embodiment

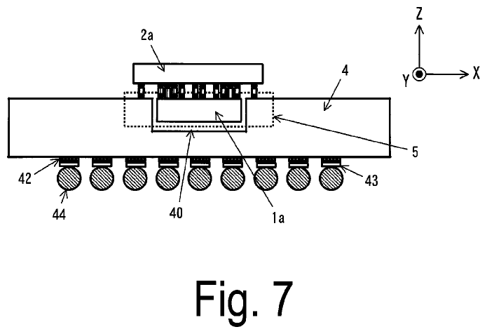

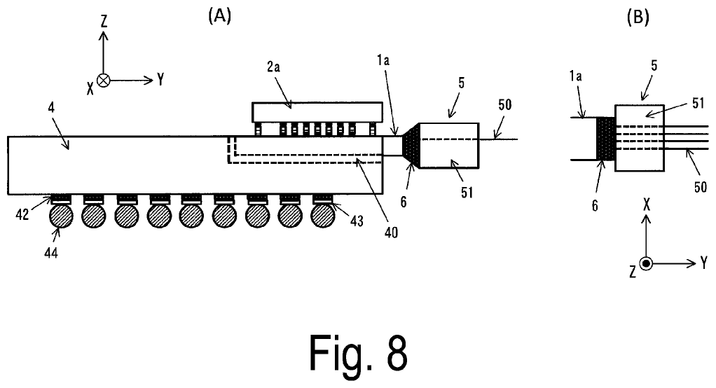

Next, a second embodiment of the present disclosure will be described. FIG. 7 is a front view of an optical transmission module according to the second embodiment of the present invention, FIG. 8(A) is a side view of the optical transmission module in FIG. 7, FIG. 8(B) is a top view of a coupling portion between the optical transmission module in FIG. 8(A) and the fiber array 5, and the identical configurations in FIGS. 1 to 3 are given the identical reference numerals. For ease of viewing the structure of the optical transmission module, the fiber array 5 is represented by a dotted line in FIG. 7.

In the optical transmission module in the present embodiment, an LD (not illustrated) is mounted on an optical semiconductor chip la, and a driver (not illustrated) for driving the LD is mounted to a semiconductor amplifier chip 2a.

The method of flip-chip mounting the optical semiconductor chip is on the semiconductor amplifier chip 2a is as described in the first embodiment with reference to FIGS. 1(A) and 1(B).

The details of the cavity structure of the extension circuit board 4, and the method of flip-chip mounting the transmission front end constituted of the semiconductor amplifier chip 2a and the optical semiconductor chip is on the extension circuit board 4 are as described in the first embodiment with reference to FIGS. 2(A) and 2(B). The method of mounting the solder balls 44 on the back surface of the extension circuit board 4 is as described in the first embodiment with reference to FIG. 3.

The light emitting/incident end face of the optical semiconductor chip is exposed from the end face of the extension circuit board 4 is adhesively fixed to the fiber array 5 using the adhesive 6. As a result, optical coupling between an optical waveguide (not illustrated) exposed at the light emitting/incident end face of the optical semiconductor chip is and the fibers 50 of the fiber array 5 is realized, thereby realizing light output from the LD of the optical semiconductor chip is to the fibers 50.

In the example in FIG. 8(A), the optical semiconductor chip is connected to the fiber array 5 by using the method described with reference to FIGS. 2(A) and 2(B). The method is not limited to this, and the method illustrated in FIGS. 4(A), 4(B), 5(A), 5(B), 6(A), and 6(B) may be employed.

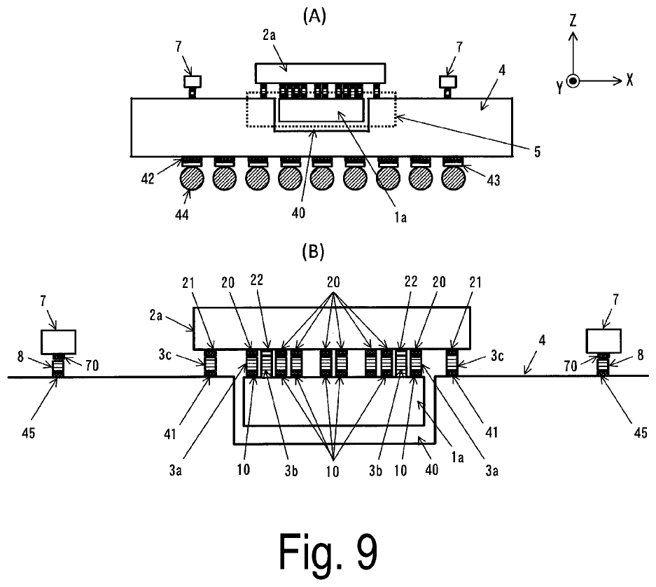

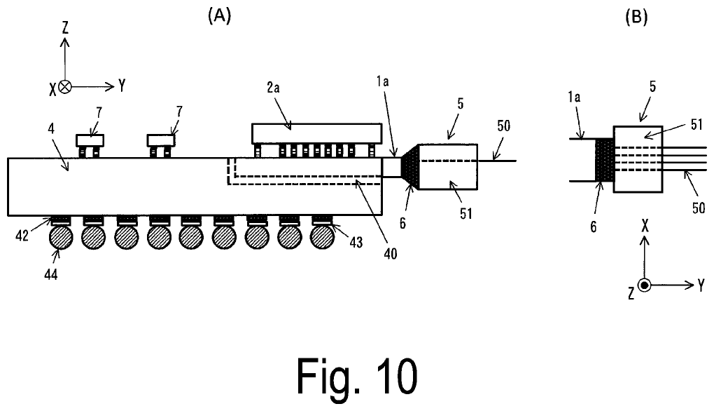

Next, as another example of the optical transmission module in the present embodiment, FIG. 9(A) illustrates a front view of the optical transmission module in the case where a capacitor 7 for cutting direct current (DC) components is mounted on the extension circuit board 4. FIG. 9(B) is an enlarged view of a bonding portion between the semiconductor amplifier chip 2a and the optical semiconductor chip is and a mounting portion of the capacitor 7. FIG. 10(A) is a side view of the optical transmission module in FIG. 9(A). FIG. 10(B) is a top view of the coupling portion between the optical transmission module in FIG. 10(A) and the fiber array 5.

To prevent the effect of external DC components on the transmission front end constituted of the semiconductor amplifier chip 2a and the optical semiconductor chip 1a, the capacitors 7 are mounted on the extension circuit board 4.

The electrode 70 of the capacitor 7 is bonded to the surface electrode 45 of the extension circuit board 4 using a conductive adhesive 8 (for example, a cream solder). In this bonding, a bump made of Au, Al, Cu, or the like may be used other than the cream solder. Thus, by mounting the capacitors 7 on the extension circuit board 4, the capacitors 7 are inserted in series into the signal line to the driver of the semiconductor amplifier chip 2a.

In the example in FIG. 10(A), the optical semiconductor chip is connected to the fiber array 5 by using the method described with reference to FIGS. 2(A) and 2(B). The method is not limited to this, and the method illustrated in FIGS. 4(A), 4(B), 5(A), 5(B), 6(A), and 6(B) may be employed.

### Third Embodiment

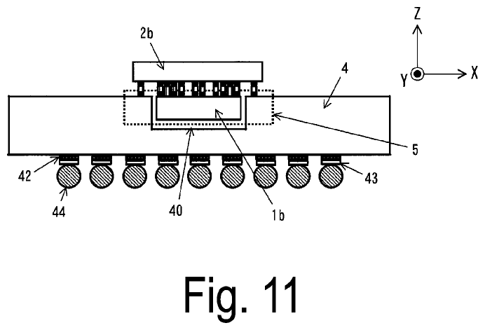

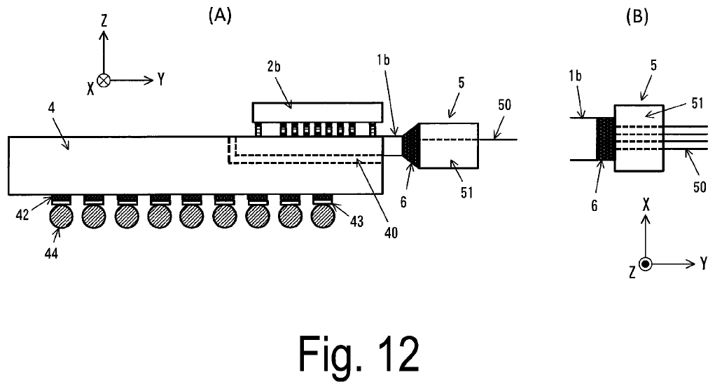

Next, a third embodiment of the present invention will be described. FIG. 11 is a front view of an optical reception module according to the third embodiment of the present invention. FIG. 12(A) is a side view of the optical reception module in FIG. 11. FIG. 12(B) is a top view of a coupling portion between the optical reception module in FIG. 12(A) and the fiber array 5. The identical components in FIGS. 1 to 3 are given the identical reference numerals. For ease of viewing the structure of the optical reception module, the fiber array 5 is represented by a dotted line in FIG. 11.

In the optical reception module in the present embodiment, a PD (not illustrated) is mounted on an optical semiconductor chip 1b, and a TIA (not illustrated) is mounted on a semiconductor amplifier chip 2b.

The method of flip-chip mounting the optical semiconductor chip 1b on the semiconductor amplifier chip 2b is as described in the first embodiment with reference to FIGS. 1(A) and 1(B). The details of the cavity structure of the extension circuit board 4, and the method of flip-chip mounting the reception front end constituted of the semiconductor amplifier chip 2b and the optical semiconductor chip 1b on the extension circuit board 4 are as described in the first embodiment with reference to FIGS. 2(A) and 2(B). The method of mounting the solder balls 44 on the back surface of the extension circuit board 4 is as described in the first embodiment with reference to FIG. 3.

The light emitting/incident end face of the optical semiconductor chip 1b exposed from the end face of the extension circuit board 4 is adhesively fixed to the fiber array 5 using the adhesive 6. As a result, optical coupling between an optical waveguide (not illustrated) exposed at the light emitting/incident end face of the optical semiconductor chip 1b and the fibers 50 of the fiber array 5 is realized, thereby realizing light input from the fibers 50 to the PD of the optical semiconductor chip 1b.

In the example in FIG. 12(A), the optical semiconductor chip 1b is connected to the fiber array 5 by using the method described with reference to FIGS. 2(A) and 2(B). The method is not limited to this, and the method illustrated in FIGS. 4(A), 4(B), 5(A), 5(B), 6(A), and 6(B) may be employed.

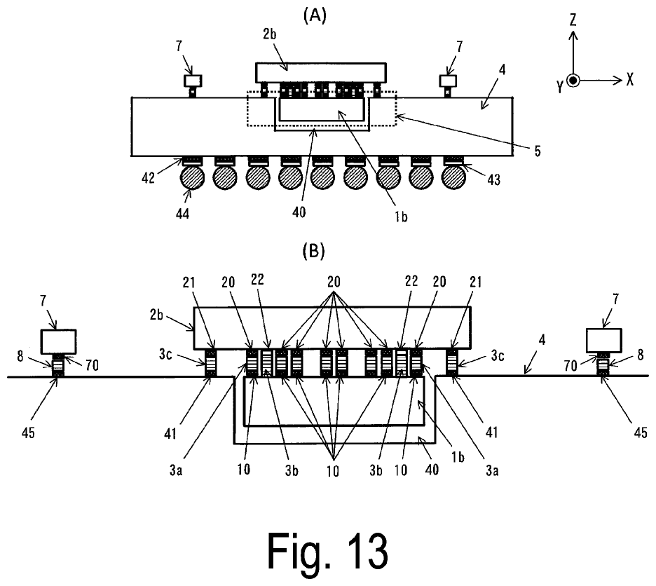

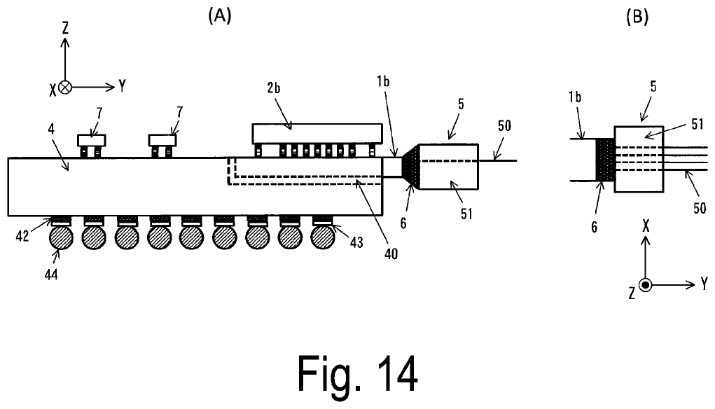

Next, as another example of the optical reception module in the present embodiment, FIG. 13(A) illustrates a front view of the optical reception module in the case where a capacitor 7 for cutting DC components is mounted on the extension circuit board 4. FIG. 13(B) is an enlarged view of a bonding portion between the semiconductor amplifier chip 2b and the optical semiconductor chip 1b and a mounting portion of the capacitor 7. FIG. 14(A) is a side view of the optical reception module in FIG. 13(A). FIG. 14(B) is a top view of the coupling portion between the optical reception module in FIG. 14(A) and the fiber array 5.

To prevent the effect of external DC components on the reception front end constituted of the semiconductor amplifier chip 2b and the optical semiconductor chip 1b, the capacitors 7 are mounted on the extension circuit board 4.

As in the case in FIGS. 9 and 10, the electrode 70 of the capacitor 7 is bonded to the surface electrode 45 of the extension circuit board 4 using a conductive adhesive 8 (for example, a cream solder). In this bonding, a bump made of Au, Al, Cu, or the like may be used other than the cream solder. By mounting the capacitors 7 on the extension circuit board 4, the capacitors 7 are inserted in series into the signal line from the TIA of the semiconductor amplifier chip 2b.

In the example in FIG. 14(A), the optical semiconductor chip 1b is connected to the fiber array 5 by using the method described with reference to FIGS. 2(A) and 2(B). The method is not limited to this, and the method illustrated in FIGS. 4(A), 4(B), 5(A), 5(B), 6(A), and 6(B) may be employed.

### Fourth Embodiment

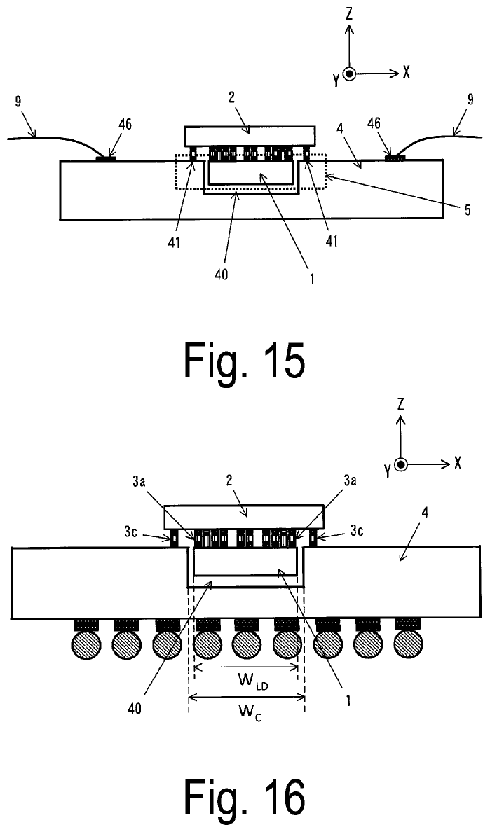

Next, a fourth embodiment of the present invention will be described. The optical transmission/reception module, the optical transmission module, and the optical reception module are BGA-mounted on the board in the first to third embodiments, respectively. Embodiments of the present invention are not limited to this, and the modules may be connected to the outside via a wire without using the BGA. FIG. 15 is a front view of the optical transmission module in the case of using wire bonding for external connection.

In the example in FIG. 15, each of surface electrodes 46 (the fifth electrodes) of the extension circuit board 4 is electrically connected to an external electrode pad (for example, an electrode pad of a package containing the optical transmission module) via a wire 9. The surface electrode 46 is electrically connected to the surface electrode 41 of the extension circuit board 4 via a wire not illustrated.

While wire bonding is applied to the optical transmission/reception module in the first example, wire bonding may be applied to the optical transmission module in the second embodiment and the optical reception module in the third embodiment.

In the first to fourth embodiments, given that a shortest distance in the X direction between the surface electrode 20 and the surface electrode 21 of the semiconductor amplifier chip 2 (2a, 2b) is x as illustrated in FIG. 3, and a width in the X direction of the recessed portion 40 of the extension circuit board 4 is We and a width in the X direction of the optical semiconductor chip 1 (1a, 1b) is WLD as illustrated in FIG. 16, an equation (1) below holds:

$$\begin{matrix}Math . 1 & \\ \frac{{W}_{C} - {W}_{LD}}{2} < x & ( 1 )\end{matrix}$$

Given that thermal expansion coefficients of the optical semiconductor chip 1 (1a, 1b), the semiconductor amplifier chip 2 (2a, 2b), and the extension circuit board 4 are A, B, and C, respectively, when a difference between A and B, a difference between B and C, or a difference between A, B, and C is within ±5%, a change in the bump due to temperature changes can be sufficiently suppressed.

### INDUSTRIAL APPLICABILITY

The present invention may be applied to optical modules used in the optical communications network.

### REFERENCE SIGNS LIST

1, 1a, 1b Optical semiconductor chip

2, 2a, 2b Semiconductor amplifier chip

3a, 3b, 3c Bump

4 Extension circuit board

5 Fiber array

6 Adhesive

7 Capacitor

8, 43 Conductive adhesive

9 Wire

10, 20, 21, 41, 45, 46 Surface electrode

22 Dummy electrode

40 Recessed portion

42 Back electrode

44 Solder ball

50 Fiber

51 Fiber block.

1.-7. (canceled)

8. An optical module comprising:
a circuit board; and
a front end structure flip-chip mounted on the circuit board, wherein the front end structure includes:
a semiconductor amplifier chip configured to execute signal processing; and
an optical semiconductor chip including a light emitting element or a light receiving element, the optical semiconductor chip being flip-chip mounted to a first surface of the semiconductor amplifier chip, wherein the circuit board has a recessed portion, wherein the semiconductor amplifier chip is flip-chip mounted on the circuit board such that the first surface of the semiconductor amplifier chip faces a second surface of the circuit board, and wherein at least a part of the optical semiconductor chip is disposed in the recessed portion of the circuit board.

9. The optical module according to claim 8, wherein:
the semiconductor amplifier chip is rectangular in a top view;
a width of at least one side of the semiconductor amplifier chip is larger than a width of the optical semiconductor chip and a width of the recessed portion of the circuit board;
the semiconductor amplifier chip includes a first electrode for connection to the optical semiconductor chip, the first electrode being disposed on the first surface of the semiconductor amplifier chip;
the semiconductor amplifier chip includes a second electrode for connection to the circuit board;
the first electrode is connected to a third electrode on a third surface of the optical semiconductor chip via a bump; and
the second electrode is connected to a fourth electrode disposed around the recessed portion of the circuit board via a bump.

10. The optical module according to claim 9, wherein:
the circuit board further includes a solder ball electrically connected to the fourth electrode, the solder ball being disposed on a back surface of the circuit board opposite to a surface of the circuit board that faces the semiconductor amplifier chip.

11. The optical module according to claim 9, wherein:
the circuit board further includes a fifth electrode wire bonded to the fourth electrode, the fifth electrode being electrically connected to the fourth electrode on a surface of the circuit board facing the semiconductor amplifier chip.

12. The optical module according to claim 8, wherein:
the semiconductor amplifier chip further includes a dummy electrode on the first surface of the semiconductor amplifier chip facing the optical semiconductor chip; and
a bump on the dummy electrode is in contact with a third surface of the optical semiconductor chip or the dummy electrode is connected to a dummy electrode on the third surface of the optical semiconductor chip via a bump.

13. The optical module according to claim 8, wherein:
the recessed portion of the circuit board extends to an end face of the circuit board; and
a fiber array is adhesively fixed to an end face of the optical semiconductor chip, the end face of the optical semiconductor chip being exposed from the circuit board, such that the optical semiconductor chip is optically coupled to fibers in the fiber array.

14. The optical module according to claim 13, wherein:
the end face of the optical semiconductor chip is flush with the end face of the circuit board; and
the fiber array is adhesively fixed to the end face of the optical semiconductor chip and the end face of the circuit board.

15. A method comprising:
providing a circuit board; and
flip-chip mounting a front end structure on the circuit board, wherein the front end structure includes:
a semiconductor amplifier chip configured to execute signal processing; and
an optical semiconductor chip including a light emitting element or a light receiving element, the optical semiconductor chip being flip-chip mounted to a first surface of the semiconductor amplifier chip, wherein the circuit board has a recessed portion, wherein the semiconductor amplifier chip is flip-chip mounted on the circuit board such that the first surface of the semiconductor amplifier chip faces a second surface of the circuit board, and wherein at least a part of the optical semiconductor chip is disposed in the recessed portion of the circuit board.

16. The method of claim 15, wherein:
the semiconductor amplifier chip is rectangular in a top view;
a width of at least one side of the semiconductor amplifier chip is larger than a width of the optical semiconductor chip and a width of the recessed portion of the circuit board;
the semiconductor amplifier chip includes a first electrode for connection to the optical semiconductor chip, the first electrode being disposed on the first surface of the semiconductor amplifier chip;
the semiconductor amplifier chip includes a second electrode for connection to the circuit board;
the first electrode is connected to a third electrode on a third surface of the optical semiconductor chip via a bump; and
the second electrode is connected to a fourth electrode disposed around the recessed portion of the circuit board via a bump.

17. The method according to claim 16, wherein:
the circuit board further includes a solder ball electrically connected to the fourth electrode, the solder ball being disposed on a back surface of the circuit board opposite to a surface of the circuit board that faces the semiconductor amplifier chip.

18. The method according to claim 16, wherein:
the circuit board further includes a fifth electrode wire bonded to the fourth electrode, the fifth electrode being electrically connected to the fourth electrode on a surface of the circuit board facing the semiconductor amplifier chip.

19. The method according to claim 15, wherein:
the semiconductor amplifier chip further includes a dummy electrode on the first surface of the semiconductor amplifier chip facing the optical semiconductor chip; and
a bump on the dummy electrode is in contact with a third surface of the optical semiconductor chip or the dummy electrode is connected to a dummy electrode on the third surface of the optical semiconductor chip via a bump.

20. The method according to claim 15, wherein:
the recessed portion of the circuit board extends to an end face of the circuit board; and
a fiber array is adhesively fixed to an end face of the optical semiconductor chip, the end face of the optical semiconductor chip being exposed from the circuit board, such that the optical semiconductor chip is optically coupled to fibers in the fiber array.

21. The method according to claim 20, wherein:
the end face of the optical semiconductor chip is flush with the end face of the circuit board; and
the fiber array is adhesively fixed to the end face of the optical semiconductor chip and the end face of the circuit board.
